(19) United States
(12) Patent Application Publication
(10) Pub. No.: US 2010/0127771 A1
(43) Pub. Date: May 27, 2010

(54) DRIVING CIRCUIT INCLUDING TESTING FUNCTION

(76) Inventor: Yuuichi SEKIYA, Miyazaki (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/624,754

(22) Filed: Nov. 24, 2009

(30) Foreign Application Priority Data
Nov. 26, 2008 (JP) 2008-300982

(51) Int. Cl. G01R 31/02

(52) U.S. Cl. 330/2

(57) ABSTRACT

The disclosure provides a driving circuit including a testing function including: an amplification circuit that amplifies an input signal and that outputs an amplified signal from an output terminal to one of a pair of input terminals of an electric device; an inversion circuit that inverts the amplified signal and that outputs an inverted signal from an output terminal to the other input terminal of the electric device; and a switching circuit that, when testing the electric device, puts the amplification circuit and the inversion circuit into a non-operating state and that switches to connect one of the output terminal of the amplification circuit or the output terminal of the inversion circuit to a first potential, and to connect the other output terminal of the amplification circuit and the output terminal of the inversion circuit to a second potential which is lower than the first electric potential.

### CROSS-REFERENCE TO RELATED APPLICATIONS

This application is based on and claims priority under 35 U.S.C. §119 from Japanese Patent Application No. 2008-300982, filed Nov. 26, 2008 the disclosure of which is incorporated by reference herein.

### RELATED ART

1. Field of the Disclosure

The disclosure relates to a driving circuit including a testing function of an electric device, such as a speaker.

2. Description of the Related Art

In a disconnection test of the speaker in a conventional speaker system, a user connects an external output terminal of an amplification device and a plus side output terminal of the speaker, and connects an input terminal and a minus side output terminal of the speaker. Then, the user turns off an operational amplifier and inputs a high level signal to the output terminal, and the user puts the input terminal into a high impedance state. Further, the user confirms the connection between the plus side output terminal of the speaker and the minus side output terminal of the speaker (Japanese Patent Application Laid-Open (JP-A) No. 2003-274491).

However, in the speaker system disclosed in JP-A No. 2003-274491, the user needs to connect a test circuit outside the amplification device when testing. Further, the above-described speaker system requires time and effort, and requires to use two terminals, the input terminal and the output terminal, when testing.

### INTRODUCTION TO THE INVENTION

The present disclosure provides a driving circuit including a testing function that does not require the user to connect the test circuit, and that can reduce the number of terminals used, by providing the test circuit in the driving circuit.

A first aspect of the disclosure is a driving circuit including a testing function including: an amplification circuit that amplifies an input signal and that outputs an amplified signal from an output terminal to one of a pair of input terminals of an electric device; an inversion circuit that inverts the amplified signal and that outputs an inverted signal from an output terminal to the other input terminal of the electric device; and a switching circuit that, when testing the electric device, puts the amplification circuit and the inversion circuit into a non-operating state and that switches to connect one of the output terminal of the amplification circuit or the output terminal of the inversion circuit to a first potential, and to connect the other output terminal of the amplification circuit and the output terminal of the inversion circuit to a second potential which is lower than the first electric potential.

In a second aspect of the present disclosure, in the above-described first aspect, a resistor may be connected between one of the output terminal of the amplification circuit or the output terminal of the inversion circuit, and one of the first potential or the second potential.

A third aspect of the disclosure is a driving circuit including a testing function including: an amplification circuit that amplifies an input signal and that outputs an amplified signal from an output terminal to one of a pair of input terminals of a speaker; an inversion circuit that inverts the amplified signal and that outputs an inverted signal from an output terminal to the other input terminal of the speaker; a first switching element which is connected between a power supply and one of the output terminal of the amplification circuit or the output terminal of the inversion circuit, and which is turned off in a normal state; a second switching element which is connected between ground and one of the output terminal of the amplification circuit or the output terminal of the inversion circuit, and which is turned off in a normal state; and a switching circuit that switches the amplification circuit and the inversion circuit to a non-operating state and that switches the first switching element and the second switching element on when testing the speaker.

In a fourth aspect of the present disclosure, in the above-described third aspect, a resistor may be connected between one of the output terminal of the amplification circuit and the output terminal of the inversion circuit, and one of the power supply or ground.

In a fifth aspect of the present disclosure, in the above-described aspects, may further include a display device that displays a result of the test.

According to the first and the third aspect, a switching circuit is provided, and therefore the present disclosure does not require the user to connect the test circuit when testing, and the number of terminals for external connection can be reduced.

According to the second aspect and the fourth aspect, the voltage can be stably suppressed, and therefore the present disclosure is effective as a measure against pop noise, and can stably test in a wide power supply voltage range and temperature range.

According to the fifth aspect of the present disclosure, a test result can be displayed on the display device.

### BRIEF DESCRIPTION OF THE DRAWINGS

Exemplary embodiments of the present disclosure will be described in detail based on the following figures, wherein:

FIG. 1 is a figure showing a circuit diagram of a speaker system according to a first exemplary embodiment;

FIG. 2 is a figure showing an output waveform of the speaker system according to the first exemplary embodiment when connected;

FIG. 3 is a figure showing an output waveform of the speaker system according to the first exemplary embodiment when disconnected; and

FIG. 4 is a figure showing a circuit diagram of the speaker system according to a second exemplary embodiment.

### DETAILED DESCRIPTION

The exemplary embodiments of the present disclosure are described and illustrated below to encompass a driving circuit including a testing function of an electric device, such as a speaker. Of course, it will be apparent to those of ordinary skill in the art that the preferred embodiments discussed below are exemplary in nature and may be reconfigured without departing from the scope and spirit of the present disclosure. However, for clarity and precision, the exemplary embodiments as discussed below may include optional steps, methods, and features that one of ordinary skill should recognize as not being a requisite to fall within the scope of the present disclosure. Hereinafter, an exemplary embodiment of the present disclosure will be described in detail with reference to the drawings.

### First Exemplary Embodiment

In a first exemplary embodiment, the present disclosure is applied to a speaker system.

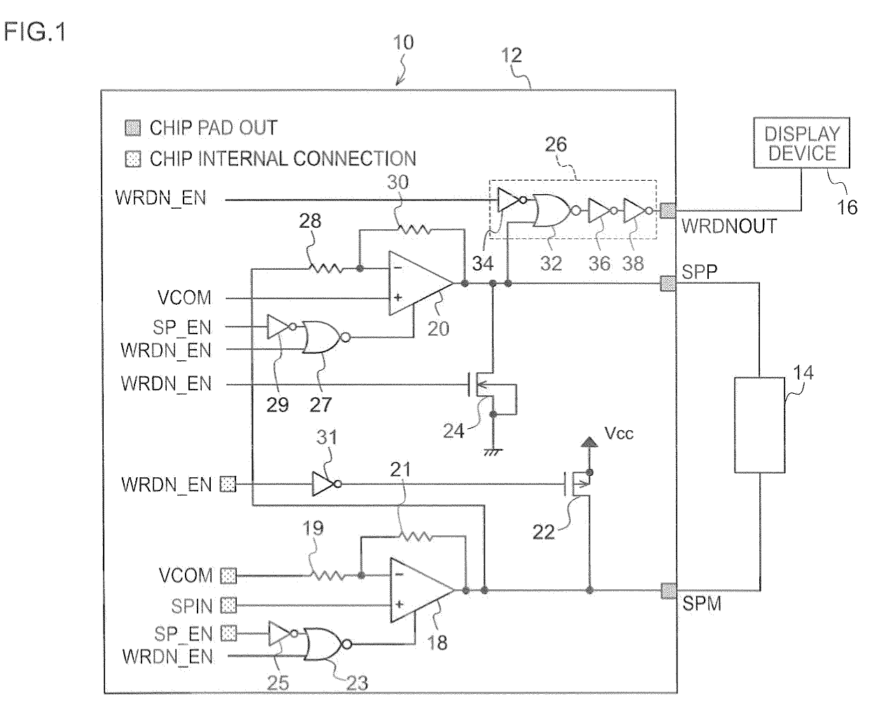

As shown in FIG. 1, a speaker system 10 according to the first exemplary embodiment is configured including, an amplifying device 12, a speaker 14 and a display device 16.

The amplifying device 12 is configured including, an operational amplifier 18, an operational amplifier 20, a P-channel type MOSFET (hereinafter also referred to as “P-MOSFET”) 22, an N-channel type MOSFET (hereinafter, also referred to as “N-MOSFET”) 24 and an output logic circuit 26. The operational amplifier 18 amplifies input signal, and outputs the amplified signal from an output terminal thereof. The operational amplifier 20 inverts the signal output from the output terminal of the operational amplifier 18, and outputs from an output terminal thereof.

A non-inverting input terminal of the operational amplifier 18 is connected to an AC power supply (hereinafter, also referred to as “SPIN”). Also, an inverting input terminal of the operational amplifier 18 is connected to a power supply (hereinafter, also referred to as “VCOM”) having a same phase of the SPIN via resistor 19, and is connected to the output terminal of the operational amplifier 18 via resistor 21. A power supply terminal of the operational amplifier 18 is connected to an enable signal supply terminal (hereinafter, also referred to as “SP_EN” terminal) for driving the operational amplifier 18 via a NOR circuit 23 and a NOT circuit 25. Together therewith, the power supply terminal of the operational amplifier 18 is connected to a disconnection test control signal supply terminal (hereinafter, also referred to as “WRDN_EN” terminal) via the NOR circuit 23. Further, the output terminal of the operational amplifier 18 is connected to a minus side output terminal (hereinafter, also referred to as “SPM” terminal) of the speaker.

A non-inverting input terminal of the operational amplifier 20 is connected to the VCOM, and an inverting input terminal is connected to the output terminal of the operational amplifier 18 via resistor 28. Together therewith, the inverting input terminal of the operational amplifier 20 is connected to the output terminal thereof via resistor 30. A power supply terminal of the operational amplifier 20 is connected to the SP_EN terminal via a NOR circuit 27 and a NOT circuit 29. Together therewith, the power supply terminal of the operational amplifier 20 is connected to the WRDN_EN terminal via the NOR circuit 27. Further, the output terminal of the operational amplifier 20 is connected to a plus side output terminal (hereinafter, also referred to as “SPP” terminal) of the speaker. Together therewith, the output terminal of the operational amplifier 20 is connected to a NOR circuit 32.

A gate terminal of the P-MOSFET 22 is connected to the WRDN EN terminal via a NOT circuit 31. Further, a source terminal of the P-MOSFET 22 is connected to a power supply V_{CC}. Furthermore, a drain terminal of the P-MOSFET 22 is connected to the output terminal of the operational amplifier 18.

A gate terminal of the N-MOSFET 24 is connected to the WRDN_EN terminal. Further, a source terminal of the N-MOSFET 24 is connected to ground. Furthermore, a drain terminal of the N-MOSFET 24 is connected to the output terminal of the operational amplifier 20.

The output logic circuit 26 is configured including the NOR circuit 32, a NOT circuit 34, a NOT circuit 36 and a NOT circuit 38. One of input terminals of the NOR circuit 32 is connected to the output terminal of the operational amplifier 20. Further, the other input terminal of the NOR circuit 32 is connected to the WRDN_EN terminal via the NOT circuit 34. The output terminal of the NOR circuit 32 is connected to an output signal detection terminal (hereinafter, also referred to as “WRDNOUT” terminal) via the NOT circuit 36 and the NOT circuit 38.

The speaker 14 includes a pair of input terminals. One of the pair of input terminals is connected to the SPP terminal of the amplifying device 12. Further, the other input terminal is connected to the SPM terminal of the amplifying device 12.

The display device 16 is configured by an LCD, or the like. The display device 16 is connected to the WRDNOUT terminal of the amplifying device 12.

Hereafter, operation during a normal operation state of the speaker system 10 according to the first exemplary embodiment will be described.

In the normal operation state, WRDN_EN signal is set to a low level (hereinafter, also referred to as “L level”), and SP_EN signal is set to a high level (hereinafter, also referred to as “H level”).

In the normal operation state, H level signal is input to the power supply terminals of the operational amplifier 18 and the operational amplifier 20. Accordingly, the operational amplifier 18 and the operational amplifier 20 are put into an operating state.

Further, H level signal is input to the gate terminal of the P-MOSFET 22, and L level signal is input to the gate terminal of the N-MOSFET 24. Accordingly, the P-MOSFET 22 and the N-MOSFET 24 are put into a non-conducting state.

A voltage obtained by amplifying a difference between a voltage input to the non-inverting input terminal and a voltage input to the inverting input terminal is output from the output terminal of the operational amplifier 18.

The voltage output from the output terminal of the operational amplifier 18 is input to the SPM terminal and the inverting input terminal of the operational amplifier 20.

A voltage obtained by amplifying a difference between a voltage input to the non-inverting input terminal and a voltage input to the inverting input terminal is output from the output terminal of the operational amplifier 20.

The voltage output from the output terminal of the operational amplifier 20 is input to the SPP terminal and one of the input terminals of the NOR circuit 32 of the output logic circuit 26.

A current that corresponds to the input voltage level, input to the SPM terminal and the SPP terminal, flows to the speaker 14.

H level signal is input to the other input terminal oldie NOR circuit 32. Further, L level signal is output from the output terminal of the NOR circuit 32. Furthermore, L level signal is input to the WRDNOUT terminal via the NOT circuit 36 and the NOT circuit 38.

The L level signal input to the WRDNOUT terminal is then output to the display device 16.

Hereafter, operation during the disconnection test of the speaker system 10, will he described.

While the disconnection test, the WRDN_EN signal is set to the H level.

Further, while the disconnection test, L level signal is input to the power supply terminals of the operational amplifier 18 and the operational amplifier 20. Accordingly, the operational amplifier 18 and the operational amplifier 20 are put into a non-operating state.

Further, L level signal is input to the gate terminal of the P-MOSFET 22. Furthermore, H level signal is input to the gate terminal of the N-MOSFET 24. Therefore, the P-MOSFET 22 and the N-MOSFET 24 are put into a conducting state.

When the speaker 14 is conducted and when the P-MOSFET 22 is in the conducting state, drain current flows through the speaker 14, the resistor 28, the resistor 30, and through the N-MOSFET 24 to the ground.

When the power supply voltage is denoted as V_{CC}, a load resistance value of the speaker 14 as R_{L}, a resistance value of the resistor 28 as R₁, a resistance value of the resistor 30 as R₂, a combined resistance value of R_{L}, R₁, and R₂ as R₀, an on-resistance value of the P-MOSFET 22 as R_{P}, and an on-resistance value of the N-MOSFET as R_{N}, a voltage V₁ input to one of the input terminals of the NOR circuit 32 of the output logic circuit 26 can be given by the following equation (1).

a. V₁=(R_{N}×V_{CC})/(R_{P}+R₀+R_{N}) (1)

The load resistance value R_{L} of the speaker 14, the resistance value R₁ of the resistor 28 and the resistance value R₂ of the resistor 30 are set in advance, such that the voltage V₁ input to one of the input terminal of the NOR circuit 32 satisfies the assumption: V₂<V_{TH}≦V₁, when the speaker 14 is conducted and a voltage V₂ is inputted to one of the input terminal of the NOR circuit 32 and when the speaker 14 is disconnected. Here, note that V_{TH} denotes a threshold voltage of the NOR circuit 32. Further, the on-resistance value R_{N} of the N-MOSFET 24 is set in advance so as to be sufficiently larger than the on-resistance value R_{P} of the P-MOSFET 22.

Hereafter, an example will be described in which R_{L}=8(Ω), R₁=80(kΩ) and R₂=80(kΩ).

In this case, the voltage V₁ input to one of the input terminals of the NOR circuit 32 becomes higher than the threshold voltage V_{TH} of the NOR circuit 32, and therefore V₁ will be determined to be at H level.

Further, H level WRDN_EN signal is inverted to L level signal via the NOT circuit 34 and is input to the other of the input terminal of the NOR circuit 32. Therefore, L level signal will be output from the output terminal of the NOR circuit 32.

The output signal output from the output terminal of the NOR circuit 32 may include a noise. However, by providing the NOT circuit 36 and the NOT circuit 38, the noise can be removed, and the L level signal is input to the WRDNOUT terminal.

The L level signal input to the WRDNOUT terminal is then output to the display device 16.

The display device 16 displays that the speaker 14 is in the conducting state based on the L level signal.

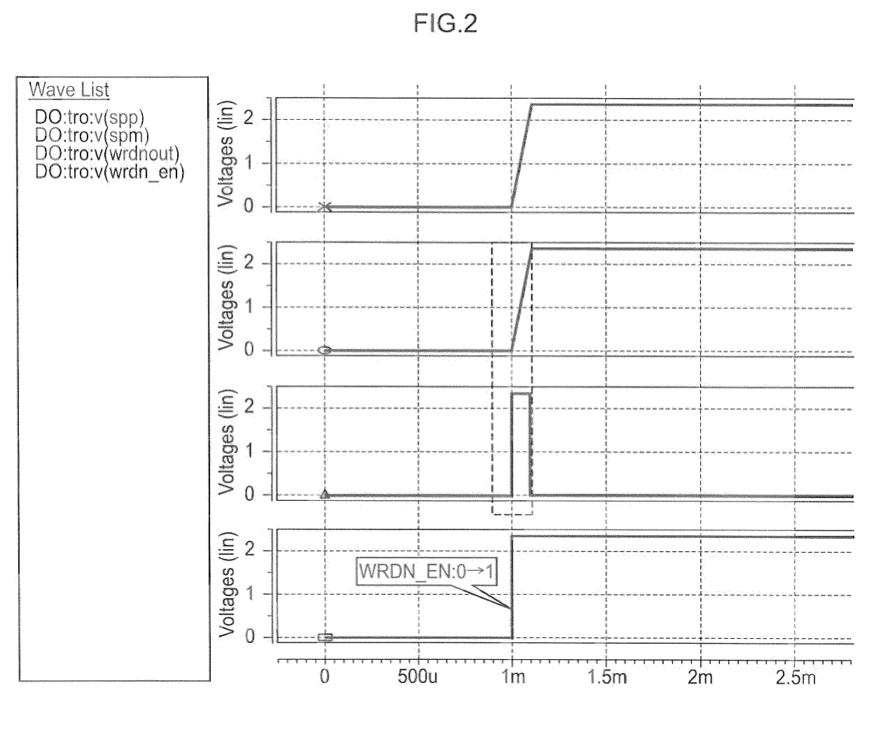

Note that, as shown in FIG. 2, from a time at which a voltage V_{wrdn}_{_{—}}ₑₙ input to the WRDN_EN terminal becomes the H level till a time at which a voltage Vₛₚₚ input to the SPP terminal becomes the maximum value, a voltage V_{wrdnout} input to the WRDNOUT terminal becomes H level. Also, the display device 16 displays that the speaker 14 is in a disconnected state based on the H level signal. Therefore, a waiting time is configured in the display device 16 so as to start the display based on the signal of V_{wrdnout} after the Vₛₚₚ becomes the maximum value.

When the speaker 14 is disconnected, and when the P-MOSFET 22 is in conducted state, the drain current flows through the resistor 28, the resistor 30 and the N-MOSFET 24 to the ground.

In such case, the voltage V₂ input to one of the input terminals of the NOR circuit 32 of the output logic circuit 26 can be given by the following equation (2).

b. V₂=(R_{N}×V_{CC})/(R_{P}+R₁+R₂+R_{N}) (2)

Further, in such case, the voltage V₂ input to one of the input terminals of the NOR circuit 32 becomes lower than the threshold voltage V_{TH} of the NOR circuit, and therefore V₂ will be determined to be at L level.

Further, L level signal is input to the other input terminal of the NOR circuit 32 as in the case when the speaker 14 is conducted. Furthermore, H level signal is output from the output terminal of the NOR circuit 32, and therefore H level signal will be input to the WRDNOUT terminal via the NOT circuit 36 and the NOT circuit 38.

Thus, H level signal input to the WRDNOUT terminal is then output to the display device 16.

Accordingly, the display device 16 displays that the speaker 14 is in the disconnected state based on the inputted H level signal.

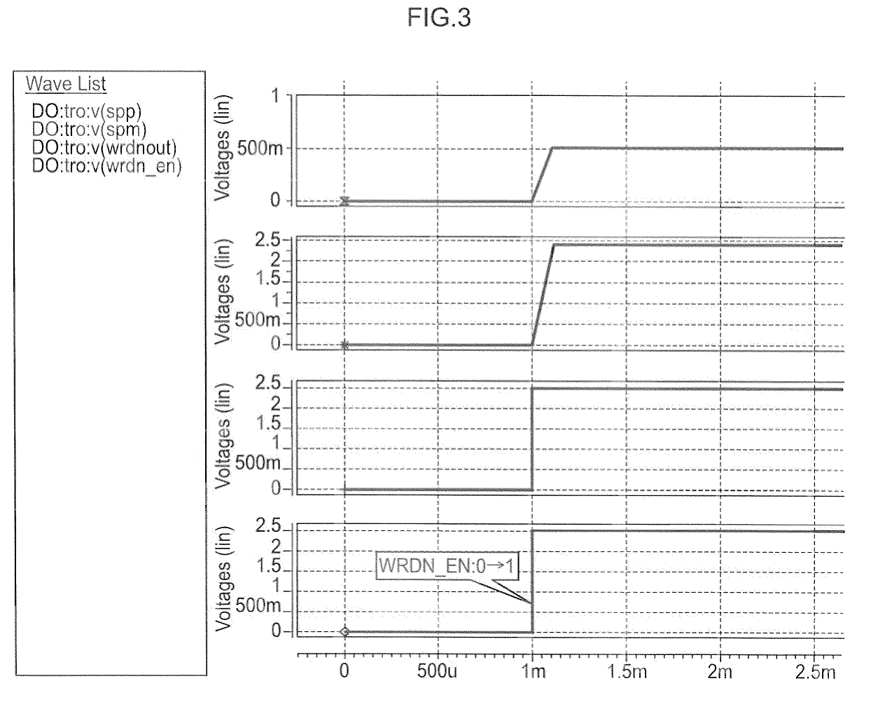

Note that, as shown in FIG. 3, the voltage Vₛₚₚ output to the SPP terminal at the disconnection state becomes a value lower than that of the conduction state.

As described above, the speaker system according to the first exemplary embodiment can test the speaker by putting the amplification circuit and the inversion circuit in the amplifying device into the non-operating state, and by switching on a first switching element and a second switching element, while testing the speaker. Therefore, the speaker system according to the first exemplary embodiment does not require the user to connect the test circuit when testing, and the number of terminals for external connection can be reduced to one.

### Second Exemplary Embodiment

Next, a second exemplary embodiment is described. Note that, the same reference numeral is given to a portions corresponding to the first exemplary embodiment and the description thereof is omitted.

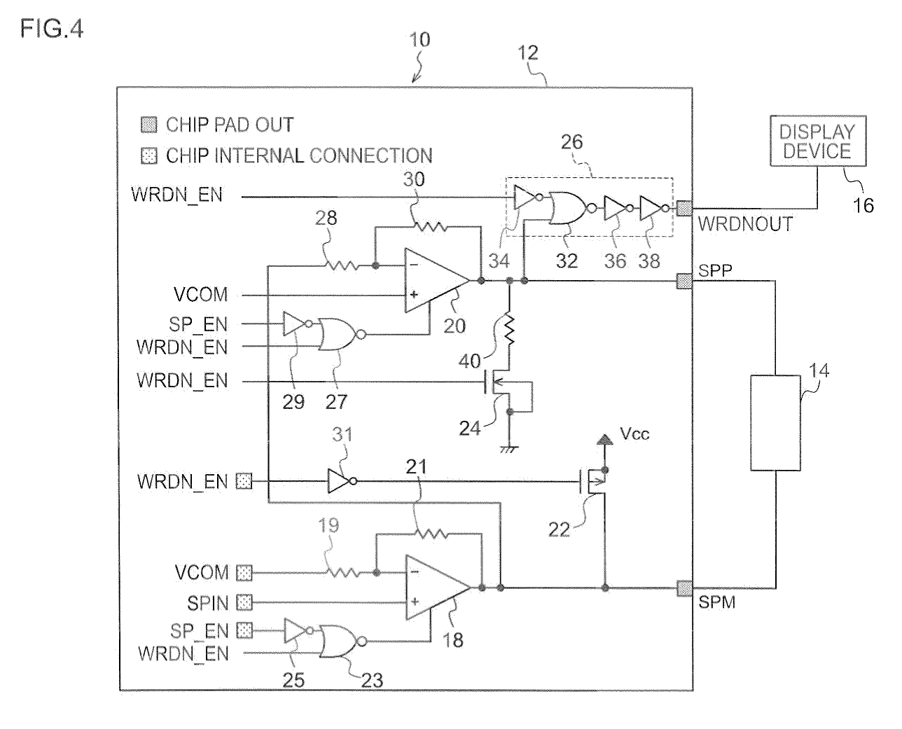

As shown in FIG. 4, in the speaker system 10 according to the second exemplary embodiment, resistor 40 is connected between the operational amplifier 20 and the N-MOSFET 24 of the amplifying device 12 of to the first exemplary embodiment.

Since the operation in the normal operation state of the speaker system 10 according to the second exemplary embodiment is similar to that of the first exemplary embodiment, the description thereof is omitted.

Hereafter, operation during the disconnection test of the speaker system 10, will be described.

When the speaker 14 is conducted, and when the P-MOSFET 22 is in conducted state, the drain current flows through, the speaker 14, the resistor 28, the resistor 30, the resistor 40, and the N-MOSFET 24 to the ground.

When the power supply voltage is denoted as V_{CC}, the load resistance value of the speaker 14 as R_{L}, the resistance value of the resistor 28 as R₁, the resistance value of the resistor 30 as R₂, the combined resistance value of R_{L}, R₁, and R₂ as R₀, the resistance value of the resistor 40 as R₃, and the on-resistance value of the P-MOSFET 22 and the on-resistance value of the N-MOSFET as R_{P} and R_{N}, respectively, a voltage V₃ input to one of the input terminals of the NOR circuit 32 of the output logic circuit can be given by the following equation (3).

c. V₃={(R_{N}+R₃)×V_{cc}}/{R_{P}+R₀+R₃+R_{N}} (3)

Further, when the voltage between the pair of input terminals of the speaker 14 is denoted as V_{L}, V_{L} can be given by the following equation (4).

d. V_{L}=(R_{L}×V_{CC})/(R_{P}+R₃+R_{N}) (4)

The voltage V₃ input to one of the input terminals of the NOR circuit 32 when the speaker 14 is conducted, and a voltage V₄ input to one of the input terminals of the NOR circuit 32 when the speaker 14 is disconnected, are set so that it satisfies the assumption: V₄<V_{TH}≦V₃. Here, note that V_{TH} denotes the threshold voltage of the NOR circuit 32. Together therewith, the load resistance value R_{L} of the speaker 14, the resistance value R₁ of the resistor 28, the resistance value R₂ of the resistor 30 and the resistance value R₃ of the resistor 40 are set in advance, such that V_{L}, becomes lower than 10 (mV). Further, the on-resistance value R_{N} of the N-MOSFET 24 is set to be equal to the on-resistance value R_{P} of the P-MOSFET 22.

Hereafter, an example will be described in which R₁=80(kΩ), R₂=80(kΩ) and R₃=40(kΩ).

In the above case, the voltage V₃ input to one of the input terminals of the NOR circuit 32 becomes higher than the threshold voltage V_{TH} of the NOR circuit 32, and therefore V₃ will be determined to be at H level.

Accordingly, when the speaker 14 is disconnected and when the P-MOSFET 22 is in conducted state, the drain current flows through the resistor 28, the resistor 30, the resistor 40, and the N-MOSFET 24, to the ground.

Namely, the voltage V₄ input to one of the input terminals of the NOR circuit 32 of the output logic circuit 26 can be given by the following equation (5)

e. V₄={(R_{N}+R₃)×V_{CC}}/(R_{P}+R₁+R₂+R₃+R_{N}) (5)

Accordingly, the voltage V₄ input to one of the input terminals of the NOR circuit 32 becomes lower than the threshold voltage V_{TH} of the NOR circuit, and therefore V₄ will be determined to be at L level.

As described above, the speaker system according to the second exemplary embodiment connects the resistor between one of the output terminal of the amplification circuit or the output terminal of the inversion circuit, and the power supply. Due thereto, the speaker system of the second exemplary embodiment can stably suppress the voltage between the pair of input terminals of the speaker when the speaker is conducting during the test, and therefore the present invention is effective as a measure against pop noise. Together therewith, the speaker system of the second exemplary embodiment can stably test in a wide power supply voltage range and temperature range, without error.

Note that, in the above-described first and second exemplary embodiment, a case in which the P-MOSFET 22 and the N-MOSFET 24 arc used was described. However, the N-MOSFET may be used instead of the P-MOSFET 22 or the P-MOSFET may be used instead of the N-MOSFET 24. When using the N-MOSFET for the P-MOSFET 22, the drain terminal of the N-MOSFET may be connected to the power supply and the source terminal may be connected to the output terminal of the operational amplifier 18. On the other hand, when using the P-MOSFET for the N-MOSFET 24, the drain terminal of the P-MOSFET may be connected to the ground and the source terminal may be connected to the output terminal of the operational amplifier 20.

In the above-described first and second exemplary embodiment, as an example, the source terminal of the P-MOSFET 22 was connected to the power supply V_{CC} and the source terminal of the N-MOSFET 24 was connected to the ground. However, the electric current only has to flow from the power supply V_{CC} through the P-MOSFET 22. the speaker 14 and the N-MOSFET 24. Therefore, a portion of a first electric potential may be connected to the source terminal of the P-MOSFET 22, and a portion of a second electric potential, lower than the first electric potential, may be connected to the source terminal of the N-MOSFET 24.

Further, in the above-described first and second exemplary embodiment, as an example, the source terminal of the P-MOSFET 22 was connected to the power supply V_{CC}, and the source terminal of the N-MOSFET 24 was connected to the ground. However, the power supply V_{CC} may be connected to the drain terminal of the N-MOSFET 24, the source terminal of the N-MOSFET 24 may be connected to the output terminal of the operational amplifier 20, the drain terminal of the P-MOSFET 22 may be connected to the ground, and the source terminal of the P-MOSFET 22 may be connected to the output terminal of the operational amplifier 18.

Further, in the above-described first and second exemplary embodiment, as an example, a case in which the present invention applied to a driving circuit of the speaker system was described. However, the present invention may be applied to the driving circuit for driving an electric device, such as a tuner.

Following from the above description and embodiment, it should be apparent to those of ordinary skill in the art that, while the foregoing constitutes an exemplary embodiment of the present disclosure, the disclosure is not necessarily limited to this precise embodiment and that changes may be made to this embodiment without departing from the scope of the invention as defined by the claims. Additionally, it is to be understood that the invention is defined by the claims and it is not intended that any limitations or elements describing the exemplary embodiment set forth herein are to be incorporated into the interpretation of any claim element unless such limitation or element is explicitly stated. Likewise, it is to be understood that it is not necessary to meet any or all of the identified advantages or objects of the disclosure discussed herein in order to fall within the scope of any claims, since the invention is defined by the claims and since inherent and/or unforeseen advantages of the present disclosure may exist even though they may not have been explicitly discussed herein.

What is claimed is:

1. A driving circuit including a testing function comprising:
an amplification circuit that amplifies an input signal and that outputs an amplified signal from an output terminal to one of a pair of input terminals of an electric device;
an inversion circuit that inverts the amplified signal and that outputs an inverted signal from an output terminal to the other input terminal of the electric device; and
a switching circuit that, when testing the electric device, puts the amplification circuit and the inversion circuit into a non-operating state and that switches to connect one of the output terminal of the amplification circuit or the output terminal of the inversion circuit to a first potential, and to connect the other output terminal of the amplification circuit and the output terminal of the inversion circuit to a second potential which is lower than the first electric potential.

2. The driving circuit including a testing function of claim 1, wherein a resistor is connected between one of the output terminal of the amplification circuit or the output terminal of the inversion circuit, and one of the first potential or the second potential.

3. The driving circuit including a testing function of claim 1, further comprising:
a display device that displays a result of the test.

4. A driving circuit including a testing function comprising:
an amplification circuit that amplifies an input signal and that outputs an amplified signal from an output terminal to one of a pair of input terminals of a speaker;
an inversion circuit that inverts the amplified signal and that outputs an inverted signal from an output terminal to the other input terminal of the speaker;
a first switching element which is connected between a power supply and one of the output terminal of the amplification circuit or the output terminal of the inversion circuit, and which is turned off in a normal state;
a second switching element which is connected between ground and one of the output terminal of the amplification circuit or the output terminal of the inversion circuit, and which is turned off in a normal state; and
a switching circuit that switches the amplification circuit and the inversion circuit to a non-operating state and that switches the first switching element and the second switching element on when testing the speaker.

5. The driving circuit including the testing function of claim 4, wherein a resistor is connected between one of the output terminal of the amplification circuit and the output terminal of the inversion circuit, and one of the power supply or ground.

6. The driving circuit including the testing function of claim 4, further comprising;
a display device that displays a result of the test.
